(19) United States
(12) Patent Application Publication
(10) Pub. No.: US 2018/0173094 A1
(43) Pub. Date: Jun. 21, 2018

(54) PROCESS FOR CONTROLLING THE SURFACE ENERGY AT THE INTERFACE BETWEEN A BLOCK COPOLYMER AND ANOTHER COMPOUND

(71) Applicants: ARKEMA FRANCE, Colombes (FR); CENTER NATIONAL DE LA RECHERCHE SCIENTIFIQUE (CNRS), Paris Cedex 14 (FR); INSTITUT POLYTECHNIQUE DE BORDEAUX, Talence Cedex (FR); UNIVERSITE DE BORDEAUX, Bordeaux (FR)

(72) Inventors: Xavier CHEVALIER, Grenoble (FR); Celia NICOLET, Sauvagnon (FR); Christophe NAVARRO, Bayonne (FR); Georges HADZIIOANNOU, Leognan (FR)

(73) Assignees: ARKEMA FRANCE, Colombes (FR); CENTER NATIONAL DE LA RECHERCHE SCIENTIFIQUE (CNRS), Paris Cedex 14 (FR); INSTITUT POLYTECHNIQUE DE BORDEAUX, Talence Cedex (FR); UNIVERSITE DE BORDEAUX, Bordeaux (FR)

(21) Appl. No.: 15/579,063

(22) PCT Filed: May 26, 2016
(86) PCT No.: PCT/FR2016/051252

§ 371 Date: Dec. 1, 2017

(30) Foreign Application Priority Data
Jun. 2, 2015 (FR) 15 54982

(51) Int. Cl. G03F 7/00; G03F 7/16; G03F 7/20

(52) U.S. Cl. CPC G03F 7/0002; G03F 7/2002; G03F 7/168

(57) ABSTRACT

The invention relates to a process for controlling the surface energy at the upper interface of a block copolymer (BCP1), the lower interface of which is in contact with a preneutralized surface of a substrate, in order to make it possible to obtain an orientation of the nanodomains of the block copolymer (BCP1) perpendicularly to the two lower and upper interfaces, the said process consisting in covering the upper surface of the block copolymer (BCP1) with an upper surface neutralization layer (TC) and being characterized in that the said upper surface neutralization layer (TC) comprises a second block copolymer (BCP2).

### FIELD OF THE INVENTION

The present invention relates to the field of the control of the surface energy at each interface of a block copolymer film, in order to control the generation of patterns and their orientation during the nanostructuring of the said block copolymer.

More particularly, the invention relates to a process for controlling the surface energy of a block copolymer at its upper interface, in contact with a compound or mixture of compounds, liquid, solid or gaseous. In addition, the invention relates to a process for the manufacture of a nanolithography resist starting from a block copolymer, the said process comprising the stages of the process for controlling the surface energy at the upper interface of the said block copolymer. Finally, the invention also relates to an upper surface neutralization layer intended to cover the upper surface of the block copolymer.

### PRIOR ART

The development of nanotechnologies has made it possible to constantly miniaturize products in the field of microelectronics and micro-electro-mechanical systems (MEMS) in particular. Today, conventional lithography techniques no longer make it possible to meet these constant needs for miniaturization, as they do not make it possible to produce structures with dimensions of less than 60 nm.

It has therefore been necessary to adapt the lithography techniques and to create etching resists which make it possible to create increasingly small patterns with a high resolution. With block copolymers, it is possible to structure the arrangement of the constituent blocks of the copolymers by phase segregation between the blocks, thus forming nanodomains, at scales of less than 50 nm. Due to this ability to be nanostructured, the use of block copolymers in the fields of electronics or optoelectronics is now well known.

However, the block copolymers intended to form nanolithography resists have to exhibit nanodomains oriented perpendicularly to the surface of the substrate, in order to be able subsequently to selectively remove one of the blocks of the block copolymer and to create a porous film with the residual block(s). The patterns thus created in the porous film can subsequently be transferred, by etching, to an underlying substrate.

Each of the blocks i, . . . j of a block copolymer, denoted BCP, exhibits a surface energy, denoted γᵢ . . . γⱼ, which is specific to it and which depends on its chemical constituents, that is to say on the chemical nature of the monomers or comonomers of which it is composed. Each of the blocks i, . . . j of the block copolymer BCP exhibits, in addition, an interaction parameter of Flory-Huggins type, denoted: χᵢₓ, when it interacts with a given material “x”, which can be a gas, a liquid, a solid surface or another polymer phase, for example, and an interfacial energy denoted “γᵢₓ”, with γᵢₓ=γᵢ−(γₓ cos θᵢₓ), where θᵢₓ is the contact angle between the materials i and x. The interaction parameter between two blocks i and j of the block copolymer is thus denoted χᵢⱼ.

Jia et al., Journal of Macromolecular Science, B, 2011, 50, 1042, have shown that there exists a relationship connecting the surface energy γᵢ and the Hildebrand solubility parameter δᵢ of a given material i. In fact, the Flory-Huggins interaction parameter between two given materials i and x is indirectly related to the surface energies γᵢ and γₓ specific to the materials. The physical phenomenon of interaction appearing at the interface of the materials is thus described either in terms of surface energies or in terms of interaction parameter.

In order to obtain a structuring of the constituent nanodomains of a block copolymer perfectly perpendicular with respect to the underlying substrate, it thus appears necessary to precisely control the interactions of the block copolymer with the different interfaces with which it is physically in contact. In general, the block copolymer is in contact with two interfaces: an interface referred to as “lower” in the continuation of the description, in contact with the underlying substrate, and an interface referred to as “upper”, in contact with another compound or mixture of compounds. In general, the compound or mixture of compounds at the upper interface is composed of ambient air or of an atmosphere of controlled composition. However, it can more generally be composed of any compound or mixture of compounds of defined constitution and of defined surface energy, whether it is solid, gaseous or liquid, that is to say non-volatile, at the temperature of self-organization of the nanodomains.

When the surface energy of each interface is not controlled, there is generally a random orientation of the patterns of the block copolymer and more particularly an orientation parallel to the substrate, this being the case whatever the morphology of the block copolymer. This parallel orientation is mainly due to the fact that the substrate and/or the compound(s) at the upper interface exhibits a preferred affinity with one of the constituent blocks of the block copolymer at the self-organization temperature of the said block copolymer. In other words, the interaction parameter of Flory-Huggins type of a block i of the block copolymer BCP with the underlying substrate, denoted χ_{i-substrate}, and/or the interaction parameter of Flory-Huggins type of a block i of the block copolymer BCP with the compound at the upper interface, for example air, denoted χᵢ₋ₐᵢᵣ, is different from zero and, equivalently, the interfacial energy γ_{i-substrate} and/or γᵢ₋ₐᵢᵣ is different from zero.

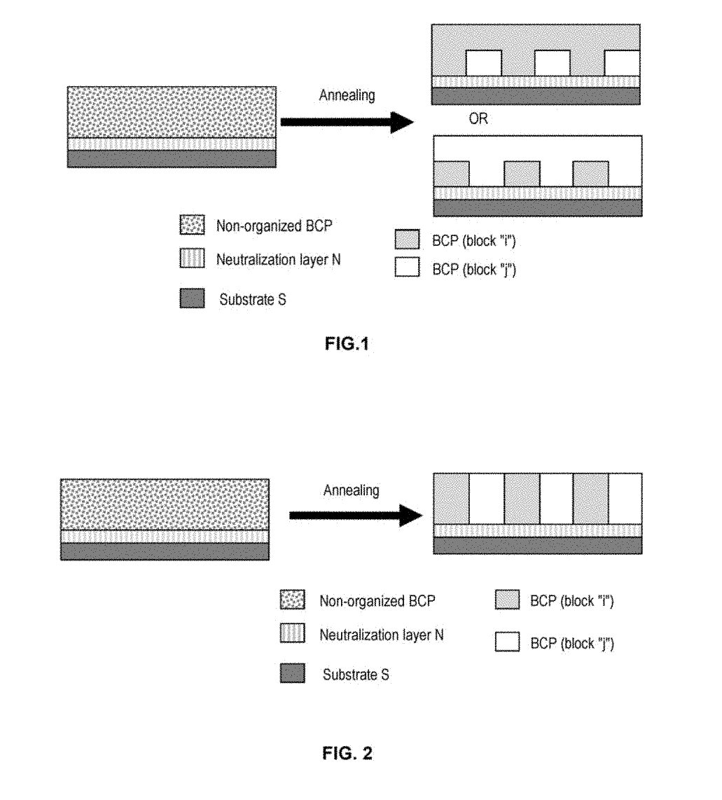

In particular, when one of the blocks of the block copolymer exhibits a preferred affinity for the compound(s) of an interface, the nanodomains then have a tendency to orient themselves parallel to this interface. The diagram of FIG. 1 illustrates the case where the surface energy at the upper interface, between a reference block copolymer BCP and ambient air in the example, is not controlled, while the lower interface between the underlying substrate and the block copolymer BCP is neutral with a Flory-Huggins parameter for each of the blocks i . . . j of the block copolymer χ_{i-substrate} and χ_{j-substrate} equal to zero or, more generally, equivalent for each of the blocks of the block copolymer BCP. In this case, a layer of one of the blocks i or j of the block copolymer BCP, exhibiting the greatest affinity with the air, becomes organized in the upper part of the film of the block copolymer BCP, that is to say at the interface with the air, and is oriented parallel to this interface.

Consequently, the desired structuring, that is to say the generation of domains perpendicular to the surface of the substrate, the patterns of which may be cylindrical, lamellar, helical or spherical, for example, requires control of the surface energies not only at the lower interface, that is to say at the interface with the underlying substrate, but also at the upper interface.

Today, the control of the surface energy at the lower interface, that is to say at the interface between the block copolymer and underlying substrate, is well known and mastered. Thus, Mansky et al., in Science. Vol. 275, pages 1458-1460 (7 Mar. 1997), have for example shown that a statistical poly(methyl methacrylate-co-styrene) copolymer (PMMA-r-PS), functionalized by a hydroxyl functional group at the chain end, makes possible good grafting of the copolymer at the surface of a silicon substrate exhibiting a layer of native oxide (Si/native SiO₂) and makes it possible to obtain a non-preferred surface energy for the blocks of the block copolymer BCP to be nanostructured. Reference is made in this case to surface “neutralization”. The key point of this approach is the obtaining of a grafted layer, making it possible to act as barrier with regard to the specific surface energy of the substrate. The interfacial energy of this barrier with a given block of the block copolymer BCP is equivalent for each of the blocks i . . . j of the block copolymer BCP and is modulated by the ratio of the comonomers present in the grafted statistical copolymer. The grafting of a statistical copolymer thus makes it possible to suppress the preferred affinity of one of the blocks of the block copolymer for the surface of the substrate and to thus prevent a preferred orientation of the nanodomains parallel to the surface of the substrate from being obtained.

In order to obtain a structuring of the nanodomains of a block copolymer BCP which is perfectly perpendicular with respect to the lower and upper interfaces, that is to say to the copolymer BCP-substrate and copolymer BCP-air interfaces in the example, it is necessary for the surface energy of the two interfaces to be equivalent with respect to the blocks of the block copolymer BCP.

When the surface energy at the upper interface of the copolymer is poorly controlled, a significant defectivity due to the non-perfect perpendicularity of the nanodomains of the block copolymer once self-assembled becomes apparent.

If the lower interface between the block copolymer BCP and the underlying substrate is today controlled, for example via the grafting of a statistical copolymer, the upper interface between the block copolymer and a compound or mixture of compounds, gaseous, solid or liquid, such as the atmosphere, for example, is markedly less controlled.

However, various approaches, described below, exist for overcoming it, the surface energy at the lower interface between the block copolymer BCP and the underlying substrate being controlled in the three approaches below.

A first solution might consist in carrying out an annealing of the block copolymer BCP in the presence of a gas mixture, making it possible to satisfy the conditions of neutrality with respect to each of the blocks of the block copolymer BCP. However, the composition of such a gas mixture appears very complex to find.

A second solution, when the mixture of compounds at the upper interface is composed of ambient air, consists in using a block copolymer BCP, the constituent blocks of which all exhibit an identical (or very similar) surface energy with respect to one another, at the self-organization temperature. In such a case, illustrated in the diagram of FIG. 2, the perpendicular organization of the nanodomains of the block copolymer BCP is obtained, on the one hand, by virtue of the copolymer BCP/substrate S interface neutralized by means of a statistical copolymer N grafted to the surface of the substrate, for example, and, on the other hand, by virtue of the fact that the blocks i . . . j of the block copolymer BCP naturally exhibit a comparable affinity for the component at the upper interface, in this case the air in the example. The situation is then χ_{i-substrate}˜ . . . ˜χ_{j-substrate} (=0 preferably) and γᵢ₋ₐᵢᵣ˜ . . . ˜γⱼ₋ₐᵢᵣ. Nevertheless, there exist only a limited number of block copolymers exhibiting this distinctive feature. This is, for example, the case of the block copolymer PS-b-PMMA. However, the Flory-Huggins interaction parameter for the copolymer PS-b-PMMA is low, that is to say of the order of 0.039, at the temperature of 150° C. of self-organization of this copolymer, which limits the minimum size of the nanodomains generated.

Furthermore, the surface energy of a given material depends on the temperature. In point of fact, if the self-organization temperature is increased, for example when it is desired to organize a block copolymer of high weight or of high period, consequently requiring a great deal of energy in order to obtain a correct organization, it is possible for the difference in surface energy of the blocks to then become too great for the affinity of each of the blocks of the block copolymer for the compound at the upper interface to be still regarded as equivalent. In this case, the increase in the self-organization temperature can then result in the appearance of defects related to the non-perpendicularity of the assemblage, as a result of the difference in surface energy between the blocks of the block copolymer at the self-organization temperature.

A final solution envisaged, described by Bates et al. in the publication entitled “Polarity-switching top coats enable orientation of sub-10 nm block copolymer domains”, Science, 2012, Vol. 338, pp 775-779, and in the document US2013 280497, consists in controlling the surface energy at the upper interface of a block copolymer to be nanostructured, of poly(trimethylsilylstyrene-b-lactide) or poly(styrene-b-trimethylsilylstyrene-b-styrene) type, by the introduction of an upper layer, also known as top coat throughout the continuation of the description, deposited at the surface of the block copolymer. In this document, the top coat, which is polar, is deposited by spin coating on the film of block copolymer to be nanostructured. The top coat is soluble in an acidic or basic aqueous solution, which allows it to be applied to the upper surface of the block copolymer, which is insoluble in water. In the example described, the top coat is soluble in aqueous ammonium hydroxide solution. The top coat is a statistical or alternating copolymer, the composition of which comprises maleic anhydride. In solution, the opening of the ring of the maleic anhydride allows the top coat to lose aqueous ammonia. During the self-organization of the block copolymer at the annealing temperature, the ring of the maleic anhydride of the top coat recloses, the top coat undergoes a transformation into a less polar state and become neutral with respect to the block copolymer, thus making possible a perpendicular orientation of the nanodomains with respect to the two lower and upper interfaces. The top coat is subsequently removed by washing in an acidic or basic solution.

Likewise, the document US 2014238954A describes the same principle as that of the document US2013 208497 but applied to a block copolymer comprising a block of silsesquioxane type.

This solution makes it possible to replace the upper interface between the block copolymer to be organized and a compound or mixture of compounds, gaseous, solid or liquid, such as air in the example, with a block copolymer-top coat, denoted BCP-TC, interface. In this case, the top coat TC exhibits an equivalent affinity for each of the blocks i . . . j of the block copolymer BCP at the assembling temperature considered (χ_{i-TC}= . . . =χ_{j-TC} (=˜0 preferably)). The difficulty of this solution lies in the deposition of the top coat itself. This is because it is necessary, on the one hand, to find a solvent which makes it possible to dissolve the top coat but not the block copolymer, if the layer of block copolymer deposited beforehand on the substrate itself neutralized is not to be dissolved, and, on the other hand, for the top coat to be able to exhibit an equivalent surface energy for each of the different blocks of the block copolymer BCP to be nanostructured, during the heat treatment.

The different approaches described above for controlling the surface energy at the upper interface of a block copolymer, deposited beforehand on a substrate, the surface of which is neutralized, generally remain too tedious and complex to be employed and do not make it possible to significantly reduce the defectivity related to the non-perfect perpendicularity of the patterns of the block copolymer. In addition, the solutions envisaged appear too complex to be able to be compatible with industrial applications.

### TECHNICAL PROBLEM

The aim of the invention is thus to overcome at least one of the disadvantages of the prior art. The invention is targeted in particular at providing an alternative solution which is simple and which can be carried out industrially, in order to be able to control the surface energy at the upper interface of a block copolymer, so as to make possible, on the one hand, a self-assembling of the blocks of the block copolymer such that the patterns generated are oriented perpendicularly to the substrate and to the upper interface and, on the other hand, a significant reduction in the defectivity related to the non-perpendicularity of the patterns.

### BRIEF DESCRIPTION OF THE INVENTION

To this end, a subject-matter of the invention is a process for controlling the surface energy at the upper interface of a block copolymer, the lower interface of which is in contact with a preneutralized surface of a substrate, in order to make it possible to obtain an orientation of the nanodomains of the said block copolymer perpendicularly to the two lower and upper interfaces, the said process consisting in covering the upper surface of the said block copolymer with an upper surface neutralization layer and being characterized in that the said upper surface neutralization layer consists of a second block copolymer.

Thus, the blocks of the block copolymer can exhibit a surface energy modulated with respect to one another so that, at the self-organization temperature of the first block copolymer, at least one of the blocks of the second block copolymer exhibits a surface energy which is neutral with respect to all of the blocks of the first block copolymer.

According to other optional characteristics of the process for controlling the surface energy:
the first block copolymer and the second block copolymer are blended in a common solvent and are deposited simultaneously, in a single stage, on the preneutralized surface of the substrate,
the two block copolymers are immiscible with one another,
the first block copolymer to be nanostructured is deposited on the preneutralized surface of the said substrate and then the second block copolymer is deposited on the first block copolymer (BCP1) in order to make possible neutralization of its upper surface,
a stage subsequent to the deposition of the two block copolymers consists in heat treating the stack obtained, comprising the substrate, a neutralization layer, the first block copolymer and the second block copolymer, so as to nanostructure at least one of the two block copolymers,
the nanostructuring of the two block copolymers is carried out in just one heat treatment stage at a single annealing temperature,
the time necessary for the organization of the second block copolymer is less than or equal to that of the first block copolymer,
the nanostructuring of the two block copolymers is carried out in several successive heat treatment stages, using different annealing temperatures and/or times, the second block copolymer becoming organized more rapidly, or at lower temperature, than the first,
the second block copolymer is non-structured at the organization temperature of the first block copolymer and the surface energy of a block, or set of blocks, of the second block copolymer is modulated by another block, or set of blocks, of the second block copolymer, so that all of the blocks of the second block copolymer exhibit an equivalent surface energy for each of the blocks of the first block copolymer.

An additional subject-matter of the invention is a process for the manufacture of a nanolithography resist starting from a block copolymer, the lower interface of which is in contact with a preneutralized surface of an underlying substrate, the said process comprising the stages of the process for controlling the surface energy at the upper interface of the said block copolymer as described above and being characterized in that, after the nanostructuring of the first block copolymer, the second block copolymer forming the upper neutralization layer and at least one of the patterns generated in the said first block copolymer are removed in order to create a film intended to act as resist.

According to other optional characteristics of the process for the manufacture of a resist:
the withdrawal of the second block copolymer, on the one hand, and of at least one of the patterns from the first block copolymer is carried out in one or more successive stages,
the withdrawal stage is carried out by dry etching or by rinsing of the second block copolymer in a solvent or mixture of solvents, in which the first block copolymer is at least partially insoluble,
prior to the withdrawal stage, a stimulus is applied over all or part of the stack consisting of the substrate, the lower neutralization layer, the first block copolymer and the second block copolymer,
the stimulus consists of exposure of all or part of the stack to UV-visible radiation, an electron beam or a liquid exhibiting acid/base or oxidation/reduction properties,
after the application of the stimulus, the second block copolymer is removed by dissolution in a solvent or mixture of solvents in which the first block copolymer is at least partially insoluble before and/or after the exposure to the stimulus,
at least one block of the first block copolymer is sensitive to the stimulus applied, so that it can be removed simultaneously with the second block copolymer.

Finally, the invention relates to an upper surface neutralization layer intended to cover the upper surface of a block copolymer, the lower interface of which is in contact with a preneutralized surface of a substrate, in order to make it possible to obtain an orientation of the nanodomains of the said block copolymer perpendicularly to the lower and upper surfaces, the said upper surface neutralization layer being characterized in that it consists of a second block copolymer.

According to other optional characteristics of the upper surface neutralization layer:
the block copolymer comprises at least two different blocks, or sets of blocks,
the block copolymer can be synthesized by any technique or combination of techniques known to a person skilled in the art,
each block of the block copolymer can consist of a set of comonomers, copolymerized together under an architecture of block, gradient, statistical, random, alternating or comb type,
the block copolymer comprises a first block, or set of blocks, the surface energy of which is the lowest of all of the constituent blocks of the two block copolymers, and a second block, or set of blocks, exhibiting a zero or equivalent affinity for each of the blocks of the first block copolymer,
the block copolymer comprises m blocks, m being an integer ≥2 and ≤11, and preferably ≤55,
the morphology of the block copolymer is preferably lamellar, without, however, excluding the other possible morphologies,
the volume fraction of each block of the block copolymer varies from 5 to 95%, with respect to the volume of the block copolymer,
the first block, or set of blocks, the energy of which is lowest, exhibits a volume fraction of between 50% and 70%, with respect to the volume of the second block copolymer,
the second block copolymer exhibits an annealing temperature which is lower than or equal to that of the first block copolymer,
the molecular weight of the block copolymer varies between 1000 and 500 000 g/mol,
each block of the block copolymer can comprise comonomers present in the backbone of the first block copolymer (BCP1),
the first block, or set of blocks, the energy of which is lowest, is soluble in a solvent or solvent mixture, so that it promotes the dissolution of the block copolymer in the said solvent or solvent mixture when it is being withdrawn,
the upper neutralization layer is in contact with a compound or mixture of compounds of defined constitution and of defined surface energy, which can be solid, gaseous or liquid at the temperature of organization of the first and second block copolymers.

Other distinctive features and advantages of the invention will become apparent on reading the description given by way of illustrative and non-limiting example, with reference to the appended Figures, which represent:

FIG. 1, already described, a diagram of a block copolymer before and after the annealing stage necessary for its self-assembling, when the surface energy at the upper interface is not controlled.

FIG. 2, already described, a diagram of a block copolymer before and after the annealing stage necessary for its self-assembling, when all the blocks of the block copolymer exhibit a comparable affinity with the compound at the upper interface,

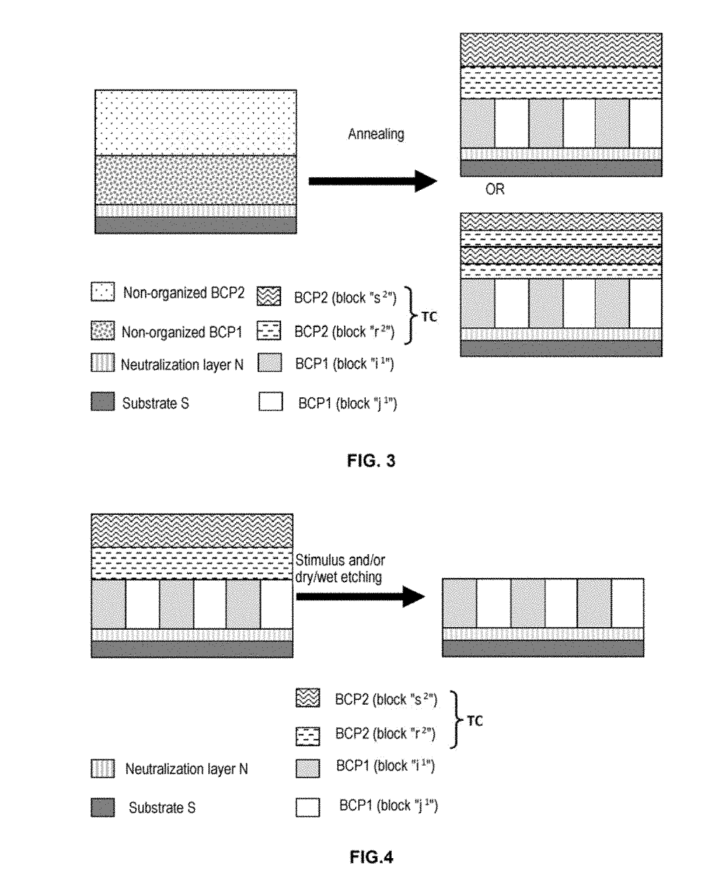

FIG. 3, a diagram of a block copolymer before and after the annealing stage necessary for its self-assembling, when the block copolymer is covered with an upper surface neutralization layer according to the invention,

FIG. 4, a diagram of a block copolymer before and after the withdrawal of the upper surface neutralization layer of FIG. 3.

### DETAILED DESCRIPTION OF THE INVENTION

The term “polymers” is understood to mean either a copolymer (of statistical, gradient, block or alternating type) or a homopolymer.

The term “monomer” as used relates to a molecule which can undergo a polymerization.

The term “polymerization” as used relates to the process for conversion of a monomer or of a mixture of monomers into a polymer.

The term “copolymer” is understood to mean a polymer bringing together several different monomer units.

The term “statistical copolymer” is understood to mean a copolymer in which the distribution of the monomer units along the chain follows a statistical law, for example of Bernoulli (zero-order Markov) or first-order or second-order Markov type. When the repeat units are distributed at random along the chain, the polymers have been formed by a Bernoulli process and are referred to as random copolymers. The term “random copolymer” is often used even when the statistical process which has prevailed during the synthesis of the copolymer is not known.

The term “gradient copolymer” is understood to mean a copolymer in which the distribution of the monomer units varies progressively along the chains.

The term “alternating copolymer” is understood to mean a copolymer comprising at least two monomer entities which are distributed alternately along the chains.

The term “block copolymer” is understood to mean a polymer comprising one or more uninterrupted sequences of each of the separate polymer entities, the polymer sequences being chemically different from one another and being bonded to one another via a chemical bond (covalent, ionic, hydrogen or coordination). These polymer sequences are also known as polymer blocks. These blocks exhibit a phase segregation parameter (Flory-Huggins interaction parameter) such that, if the degree of polymerization of each block is greater than a critical value, they are not miscible with one another and separate into nanodomains.

The term “miscibility” is understood to mean the ability of two or more compounds to blend together completely to form a homogeneous phase. The miscible nature of a blend can be determined when the sum of the glass transition temperatures (Tg) of the blend is strictly less than the sum of the Tg values of the compounds taken in isolation.

In the description, reference is made both to “self-assembling” and to “self-organization” or also to “nanostructuring” to describe the well-known phenomenon of phase separation of the block copolymers, at an assembling temperature also known as annealing temperature.

The term “lower interface” of a block copolymer to be nanostructured is understood to mean the interface in contact with an underlying substrate on which a film of the said block copolymer is deposited. It is noted that, throughout the continuation of the description, this lower interface is neutralized by a technique known to a person skilled in the art, such as the grafting of a statistical copolymer to the surface of the substrate prior to the deposition of the film of block copolymer, for example.

The term “upper interface” or “upper surface” of a block copolymer to be nanostructured is understood to mean the interface in contact with a compound or mixture of compounds of defined constitution and of defined surface energy, whether it is solid, gaseous or liquid, that is to say non-volatile, at the temperature of self-organization of the nanodomains. In the example described in the continuation of the description, this mixture of compounds is composed of ambient air but the invention is not in any way limited to this scenario. Thus, when the compound at the upper interface is gaseous, this can also be a controlled atmosphere, when the compound is liquid, this can be a solvent or mixture of solvents in which the block copolymer is insoluble and, when the compound is solid, this can, for example, be another substrate, such as a silicon substrate, for example.

The principle of the invention consists in covering the upper surface of a block copolymer to be nanostructured, referenced BCP1 in the continuation, itself deposited beforehand on an underlying substrate S, the surface of which has been neutralized by grafting with a layer N of statistical copolymer, for example, with an upper layer, denoted top coat subsequently and referenced TC, the composition of which makes possible control of the surface energy at the upper interface of the said block copolymer BCP1. Such a top coat TC layer then makes it possible to orientate the patterns generated during the nanostructuring of the block copolymer BCP1, whether these are of cylindrical, lamellar or other morphology, perpendicularly to the surface of the underlying substrate S and to the upper surface.

For this, the top coat TC layer is advantageously composed of a second block copolymer, referenced BCP2 subsequently. Preferably the second block copolymer BCP2 comprises at least two different blocks, or sets of blocks.

Preferably, this second block copolymer BCP2 comprises, on the one hand, a block, or a set of blocks, referenced “s²”, the surface energy of which is lowest of all of the constituent blocks of the two block copolymers BCP1 and BCP2, and, on the other hand, a block, or a set of blocks, referenced “r²”, exhibiting a zero affinity with all of the blocks of the first block copolymer BCP1 to be nanostructured.

The term “set of blocks” is understood to mean blocks exhibiting an identical or similar surface energy.

The underlying substrate S can be a solid of inorganic, organic or metallic nature.

As regards the film of block copolymer to be nanostructured, denoted BCP1, it comprises “n” blocks, n being an integer greater than or equal to 2 and preferably less than 11 and more preferably less than 4. The copolymer BCP1 is more particularly defined by the following general formula:

A¹-b-B¹-b-C¹-b-D¹-b- . . . -b-Z¹

where A¹, B¹, C¹, D¹, . . . , Z¹ are so many blocks “i¹” . . . “j¹” representing either pure chemical entities, that is to say that each block is a set of monomers of identical chemical natures, polymerized together, or a set of comonomers, copolymerized together, in the form, in all or part, of a block or statistical or random or gradient or alternating copolymer.

Each of the blocks “i¹” . . . “j¹” of the block copolymer BCP1 to be nanostructured can thus potentially be written in the form: i¹=aᵢ¹-co-bᵢ¹-co- . . . -co-zᵢ¹, with i¹≠ . . . ≠j¹, in all or part.

The volume fraction of each entity aᵢ¹ . . . zᵢ¹ can range from 1 to 100% in each of the blocks i¹ . . . j¹ of the block copolymer BCP1.

The volume fraction of each of the blocks i¹ . . . j¹ can range from 5 to 95% of the block copolymer BCP1.

The volume fraction is defined as being the volume of an entity with respect to that of a block, or the volume of a block with respect to that of the block copolymer.

The volume fraction of each entity of a block of a copolymer, or of each block of a block copolymer, is measured in the way described below. Within a copolymer in which at least one of the entities, or one of the blocks, if a block copolymer is concerned, comprises several comonomers, it is possible to measure, by proton NMR, the molar fraction of each monomer in the entire copolymer and then to work back to the mass fraction by using the molar mass of each monomer unit. In order to obtain the mass fractions of each entity of a block, or each block of a copolymer, it is then sufficient to add the mass fractions of the constituent comonomers of the entity or of the block. The volume fraction of each entity or block can subsequently be determined from the mass fraction of each entity or block and from the density of the polymer which the entity or the block forms. However, it is not always possible to obtain the density of the polymers, the monomers of which are copolymerized. In this case, the volume fraction of an entity or of a block is determined from its mass fraction and from the density of the compound which is predominant by weight in the entity or in the block.

The molecular weight of the block copolymer BCP1 can range from 1000 to 500000 g·mol⁻¹.

The block copolymer BCP1 can exhibit any type of architecture: linear, star-branched (three or multiple arms), grafted, dendritic or comb.

As regards the second block copolymer, denoted BCP2, constituent of the upper neutralization layer, also known as top coat and referenced TC, it is more particularly defined by the following general formula:

A²-b-B²-b-C²- . . . -b-Z²,

in which A², B², C², D², . . . , Z² are so many blocks “i²” . . . “j²” representing either pure chemical entities, that is to say that each block is a set of monomers of identical chemical natures, polymerized together, or a set of comonomers, copolymerized together, in the form, in all or part, of a block or statistical or random or gradient or alternating copolymer.

Each block “i²” . . . “j²” of the block copolymer BCP2 can be composed of any number of comonomers, of any chemical nature, optionally including comonomers present in the backbone of the first block copolymer BCP1 to be nanostructured, over all or part of the constituent block copolymer BCP2 of the top coat.

Each block “i²” . . . “j²” of the block copolymer BCP2 comprising comonomers can be without distinction copolymerized in the form of a block or random or statistical or alternating or gradient copolymer over all or part of the blocks of the block copolymer BCP2. In order of preference, it is copolymerized in the form of a random, or gradient or statistical or alternating copolymer.

The blocks “i²” . . . “j²” of the block copolymer BCP2 can be different from one another, either in the nature of the comonomers present in each block, or in their number, or be identical two by two, as long as there exist at least two different blocks, or sets of blocks, in the block copolymer BCP2.

Advantageously, one of the blocks, or set of blocks, denoted “s²”, of the constituent block copolymer BCP2 of the top coat exhibits the lowest surface energy of all of the blocks of the two block copolymers BCP1 and BCP2. Thus, at the annealing temperature necessary to nanostructure the second block copolymer BCP2, and if this annealing temperature is greater than the glass transition temperature of the first block copolymer BCP1, the block “s²” of the second block copolymer BCP2 comes into contact with the compound at the upper interface and is then oriented parallel to the upper surface of the stack of layers composed of the substrate S, the neutralization layer N, the film of block copolymer BCP1 to be nanostructured and the block copolymer BCP2 forming the top coat TC. In the example described, the compound at the upper interface is composed of a gas and more particularly of ambient air. The gas can also be a controlled atmosphere, for example. The greater the difference in surface energy of the block, or set of blocks, “s²” from the other blocks of the two block copolymers BCP1 and BCP2, the more its interaction with the compound at the upper interface, in this case air in the example, is favoured, which also favours the effectiveness of the layer of top coat TC. The difference in surface energy of this block “s²” from the other blocks of the two copolymers thus has to exhibit a value sufficient to make it possible for the block “s²” to be found at the upper interface. The situation is then χₛ₂₋ₐᵢᵣ˜0, . . . , χᵢ₁₋ₐᵢᵣ>0, . . . , χⱼ₁₋ₐᵢᵣ>0, χᵢ₂₋ₐᵢᵣ>0, . . . , χⱼ₂₋ₐᵢᵣ>0.

In order to obtain a perpendicular orientation of the patterns generated by the nanostructuring of the first block copolymer BCP1, it is preferable for the second block copolymer BCP2 to be preassembled or else for it to be able to become self-organized at the same annealing temperature but with faster kinetics. The annealing temperature at which the second block copolymer becomes self-organized is thus preferably less than or equal to the annealing temperature of the first block copolymer BCP1.

Preferably, the block “s²” which has the lowest surface energy of all the blocks of the block copolymers BCP1 and BCP2 is also that which has the greatest volume fraction of the block copolymer BCP2. Preferably, its volume fraction can range from 50 to 70%, with respect to the total volume of the block copolymer BCP2.

As well as the first condition with regard to the block “s²”, another block, or set of blocks, denoted “r²”, of the constituent block copolymer BCP2 of the top coat has in addition to exhibit a zero affinity for all the blocks of the first block copolymer BCP1 to be nanostructured. Thus, the block “r²” is “neutral” with regard to all the blocks of the first block copolymer BCP1. The situation is then χᵢ₁₋ᵣ₂= . . . =χⱼ₁₋ᵣ₂ (=˜0 preferably) and χᵢ₁₋ᵢ₂>0, . . . , χⱼ₁₋ⱼ₂>0. The block “r²” then makes it possible to neutralize and control the upper interface of the first block copolymer BCP1 and thus contributes, with the block “s²”, to the orientation of the nanodomains of the copolymer BCP1 perpendicularly to the lower and upper surfaces of the stack. The block “r²” can be defined according to any method known to a person skilled in the art in order to obtain a material “neutral” for a given block copolymer BCP1, such as, for example, a copolymerization in the statistical form of the comonomers constituting the first block copolymer BCP1 according to a precise composition.

By virtue of the combined action of these two blocks, or sets of blocks, “s²” and “r²” of the block copolymer BCP2 forming the top coat TC layer, it is possible to obtain a stack as illustrated in the diagram of FIG. 3, leading to a perpendicular structuring of the patterns of the first block copolymer BCP1 with respect to its lower and upper surfaces. In this FIG. 3, the constituent block copolymer BCP2 of the top coat is self-assembled and the block “s²” is found oriented parallel to the interface with ambient air and the block “r²” is found oriented parallel to the interface with the blocks of the film of block copolymer BCP1, thus making possible a perpendicular organization of the patterns of the block copolymer BCP1.

Advantageously, the block copolymer BCP2 is composed of “m” blocks, m being an integer ≥2 and preferably less than or equal to 11 and more preferably less than or equal to 5.

The period of the self-organized patterns of the BCP2, denoted L₀₂, can have any value. Typically, it is located between 5 and 100 nm. The morphology adopted by the block copolymer BCP2 can also be any morphology, that is to say lamellar, cylindrical, spherical or more exotic. Preferably, it is lamellar.

The volume fraction of each block can vary from 5 to 95%, with respect to the volume of the block copolymer BCP2. Preferably but non-limitingly, at least one block will exhibit a volume fraction which can range from 50 to 70% of the volume of the block copolymer BCP2. Preferably, this block, representing the greatest volume fraction of the copolymer, consists of the block, or set of blocks, “s²”.

The molecular weight of the BCP2 can vary from 1000 to 500 000 g/mol. Its molecular dispersity can be between 1.01 and 3.

The block copolymer BCP2 can be synthesized by any appropriate polymerization technique, or combination of polymerization techniques, known to a person skilled in the art, such as, for example, anionic polymerization, cationic polymerization, controlled or uncontrolled radical polymerization or ring opening polymerization. In this case, the different constituent comonomer(s) of each block will be chosen from the standard list of the monomers corresponding to the chosen polymerization technique.

When the polymerization process is carried out by a controlled radical route, for example, any controlled radical polymerization technique can be used, whether it is NMP (“Nitroxide Mediated Polymerization”), RAFT (“Reversible Addition and Fragmentation Transfer”), ATRP (“Atom Transfer Radical Polymerization”), INIFERTER (“Initiator-Transfer-Termination”), RITP (“Reverse Iodine Transfer Polymerization”) or ITP (“Iodine Transfer Polymerization”). Preferably, the polymerization process by a controlled radical route will be carried out by NMP.

More particularly, the nitroxides resulting from the alkoxyamines derived from the stable free radical (1) are preferred.

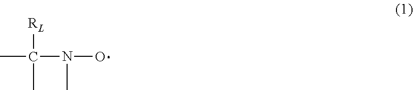

in which the radical R_{L} exhibits a molar mass of greater than 15.0342 g/mol. The radical R_{L} can be a halogen atom, such as chlorine, bromine or iodine, a saturated or unsaturated and linear, branched or cyclic hydrocarbon group, such as an alkyl or phenyl radical, or an ester group COOR or an alkoxyl group OR or a phosphonate group PO(OR)₂, as long as it exhibits a molar mass of greater than 15.0342. The radical R_{L}, which is monovalent, is said to be in the β position with respect to the nitrogen atom of the nitroxide radical. The remaining valencies of the carbon atom and of the nitrogen atom in the formula (1) can be bonded to various radicals, such as a hydrogen atom or a hydrocarbon radical, for instance an alkyl, aryl or arylalkyl radical, comprising from 1 to 10 carbon atoms. It is not out of the question for the carbon atom and the nitrogen atom in the formula (1) to be connected to one another via a divalent radical, so as to form a ring. Preferably however, the remaining valencies of the carbon atom and of the nitrogen atom of the formula (1) are bonded to monovalent radicals. Preferably, the radical R_{L} exhibits a molar mass of greater than 30 g/mol. The radical R_{L} can, for example, have a molar mass of between 40 and 450 g/mol. By way of example, the radical R_{L} can be a radical comprising a phosphoryl group, it being possible for the said radical R_{L} to be represented by the formula:

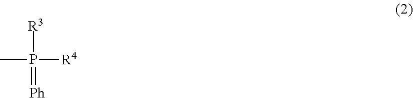

in which R³ and R⁴, which can be identical or different, can be chosen from alkyl, cycloalkyl, alkoxyl, aryloxyl, aryl, aralkyloxy, perfluoroalkyl or aralkyl radicals and can comprise from 1 to 20 carbon atoms. R³ and/or R⁴ can also be a halogen atom, such as a chlorine or bromine or fluorine or iodine atom. The radical R_{L} can also comprise at least one aromatic ring, such as for the phenyl radical or the naphthyl radical, it being possible for the latter to be substituted, for example with an alkyl radical comprising from 1 to 4 carbon atoms.

More particularly, the alkoxyamines derived from the following stable radicals are preferred:
N-(tert-butyl)-1-phenyl-2-methylpropyl nitroxide,
N-(tert-butyl)-1-(2-naphthyl)-2-methylpropyl nitroxide,
N-(tert-butyl)-1-diethylphosphono-2,2-dimethyl propyl nitroxide,
N-(tert-butyl)-1-dibenzylphosphono-2,2-dimethylpropyl nitroxide,
N-phenyl-1-diethylphosphono-2,2-dimethylpropyl nitroxide,
N-phenyl-1-diethylphosphono-1-methylethyl nitroxide,
N-(1-phenyl-2-methylpropyl)-1-diethylphosphono-1-methylethyl nitroxide,
4-oxo-2,2,6,6-tetramethyl-1-piperidinyloxy,
2,4,6-tri(tert-butyl)phenoxy.

Preferably, the alkoxyamines derived from N-(tert-butyl)-1-diethylphosphono-2,2-dimethylpropyl nitroxide will be used.

The constituent comonomers of the polymers synthesized by the radical route will, for example, be chosen from the following monomers: vinyl, vinylidene, diene, olefinic, allyl, (meth)acrylic or cyclic monomers. These monomers are more particularly chosen from vinylaromatic monomers, such as styrene or substituted styrenes, in particular α-methylstyrene, acrylic monomers, such as acrylic acid or its salts, alkyl, cycloalkyl or aryl acrylates, such as methyl, ethyl, butyl, ethylhexyl or phenyl acrylate, hydroxyalkyl acrylates, such as 2-hydroxyethyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or their mixtures, aminoalkyl acrylates, such as 2-(dimethylamino)ethyl acrylate (ADAME), fluoroacrylates, silylated acrylates, phosphorus-comprising acrylates, such as alkylene glycol acrylate phosphates, glycidyl acrylate or dicyclopentenyloxyethyl acrylate, methacrylic monomers, such as methacrylic acid or its salts, alkyl, cycloalkyl, alkenyl or aryl methacrylates, such as methyl (MMA), lauryl, cyclohexyl, allyl, phenyl or naphthyl methacrylate, hydroxyalkyl methacrylates, such as 2-hydroxyethyl methacrylate or 2-hydroxypropyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycol-polypropylene glycol methacrylates or their mixtures, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloyloxypropyltrimethylsilane, phosphorus-comprising methacrylates, such as alkylene glycol methacrylate phosphates, hydroxyethylimidazolidone methacrylate, hydroxyethylimidazolidinone methacrylate or 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamidopropyltrimethylammonium chloride (MAPTAC), glycidyl methacrylate, dicyclopentenyloxyethyl methacrylate, itaconic acid, maleic acid or its salts, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, 1,1-diphenylethylene, hexene and 1-octene, diene monomers, including butadiene or isoprene, as well as fluoroolefinic monomers and vinylidene monomers, among which may be mentioned vinylidene fluoride, which are if appropriate protected in order to be compatible with the polymerization processes.

When the polymerization process is carried out by an anionic route, any anionic polymerization mechanism can be considered, whether ligated anionic polymerization or ring-opening anionic polymerization.

Preferably, use will be made of an anionic polymerization process in a nonpolar solvent and preferably toluene, such as described in Patent EP 0 749 987, and which involves a micromixer.

When the polymers are synthesized by the cationic or anionic route or by ring opening, the constituent comonomer or comonomers of the polymers will, for example, be chosen from the following monomers: vinyl, vinylidene, diene, olefinic, allyl, (meth)acrylic or cyclic monomers. These monomers are more particularly chosen from vinylaromatic monomers, such as styrene or substituted styrenes, in particular α-methylstyrene, silylated styrenes, acrylic monomers, such as alkyl, cycloalkyl or aryl acrylates, such as methyl, ethyl, butyl, ethylhexyl or phenyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or their mixtures, aminoalkyl acrylates, such as 2-(dimethylamino)ethyl acrylate (ADAME), fluoroacrylates, silylated acrylates, phosphorus-comprising acrylates, such as alkylene glycol acrylate phosphates, glycidyl acrylate or dicyclopentenyloxyethyl acrylate, alkyl, cycloalkyl, alkenyl or aryl methacrylates, such as methyl (MMA), lauryl, cyclohexyl, allyl, phenyl or naphthyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycol-polypropylene glycol methacrylates or their mixtures, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloyloxypropyltrimethylsilane, phosphorus-comprising methacrylates, such as alkylene glycol methacrylate phosphates, hydroxyethylimidazolidone methacrylate, hydroxyethylimidazolidinone methacrylate or 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamidopropyltrimethylammonium chloride (MAPTAC), glycidyl methacrylate, dicyclopentenyloxyethyl methacrylate, itaconic acid, maleic acid or its salts, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, 1,1-diphenylethylene, hexene and 1-octene, diene monomers, including butadiene or isoprene, as well as fluoroolefinic monomers and vinylidene monomers, among which may be mentioned vinylidene fluoride, cyclic monomers, among which may be mentioned lactones, such as ε-caprolactone, lactides, glycolides, cyclic carbonates, such as trimethylene carbonate, siloxanes, such as octamethylcyclotetrasiloxane, cyclic ethers, such as trioxane, cyclic amides, such as ε-caprolactam, cyclic acetals, such as 1,3-dioxolane, phosphazenes, such as hexachlorocyclotriphosphazene, N-carboxyanhydrides, epoxides, cyclosiloxanes, phosphorus-comprising cyclic esters, such as cyclophosphorinanes, cyclophospholanes, oxazolines, which are if appropriate protected in order to be compatible with the polymerization processes, or globular methacrylates, such as isobornyl methacrylate, halogenated isobornyl methacrylate, halogenated alkyl methacrylate or naphthyl methacrylate, alone or as a mixture of at least two abovementioned monomers.

As regards the process for controlling the surface energy at the upper interface of the first block copolymer BCP1, the second block copolymer BCP2 forming the top coat TC layer can be deposited on the film of block copolymer BCP1, itself predeposited on an underlying substrate S, the surface of which has been neutralized N by any means known to a person skilled in the art, or else it can be deposited simultaneously with the first block copolymer BCP1.

Whether the two block copolymers BCP1 and BCP2 are deposited successively or simultaneously, they can be deposited on the surface of the substrate S neutralized beforehand N, according to techniques known to a person skilled in the art, such as, for example, the spin coating, doctor blade, knife system or slot die system technique.

According to a preferred embodiment, the two block copolymers BCP1 and BCP2 have a common solvent, so that they can be deposited on the underlying substrate S, the surface of which has been neutralized beforehand, in one and the same stage. For this, the two copolymers are dissolved in the common solvent and form a blend of any proportions. The proportions can, for example, be chosen as a function of the thickness desired for the film of block copolymer BCP1 intended to act as nanolithography resist.

However, the two copolymers BCP1 and BCP2 must not be miscible with one another or at least only very slightly miscible, in order to prevent the second copolymer BCP2 from disrupting the morphology adopted by the first block copolymer BCP1.

The blend of block copolymers BCP1+BCP2 can then be deposited on the surface of the substrate according to techniques known to a person skilled in the art, such as, for example, the spin coating, doctor blade, knife system or slot die system technique.

Subsequent to the deposition of the two block copolymers BCP1 and BCP2, successively or simultaneously, a stack of layers is thus obtained comprising the substrate S, a neutralization layer N, the first block copolymer BCP1 and a second block copolymer BCP2.

The block copolymer BCP2 forming the top coat TC layer exhibits the well-known phenomenon of block copolymers of phase separation at an annealing temperature.

The stack obtained is then subjected to a heat treatment, so as to nanostructure at least one of the two block copolymers

Preferably, the second block copolymer BCP2 nanostructures first, in order for its lower interface to be able to exhibit a neutrality with respect to the first block copolymer BCP1 during its self-organizing. For this, the annealing temperature of the second block copolymer BCP2 is preferably less than or equal to the annealing temperature of the first block copolymer BCP1 while being greater than the highest glass transition temperature of the BCP1. In addition, when the annealing temperatures are identical, that is to say when the two block copolymers can self-assemble in a single stage at the same annealing temperature, the time necessary for the organization of the second block copolymer BCP2 is preferably less than or equal to that of the first block copolymer.

When the annealing temperatures of the two block copolymers BCP1 and BCP2 are identical, the first block copolymer BCP1 becomes self-organized and generates patterns, while the second block copolymer BCP2 also develops a structure, so to have at least two distinct domains “s²” and “r². The situation is thus preferably χₛ₂₋ᵣ₂·Nₜ>10.5, where Nt is the total degree of polymerization of the blocks “s²” and “r²”, for a strictly symmetrical block copolymer BCP2. Such a copolymer is symmetrical when the volume fractions of each block constituting the BCP2 copolymer are equivalent, in the absence of particular interactions or of specific phenomena of frustration between different blocks of the block copolymer BCP2, leading to a distortion of the phase diagram relating to the copolymer BCP2. More generally, it is advisable for χₛ₂₋ᵣ₂·Nt to be greater than a curve describing the phase separation limit, called MST (Microphase Separation Transition), between an ordered system and a disordered system, dependant on the intrinsic composition of the block copolymer BCP2. This condition is, for example, described by L. Leibler in the document entitled “Theory of microphase separation in block copolymers”, Macromolecules, 1980, Vol. 13, pp 1602-1617.

However, it may be that, in an alternative embodiment, the block copolymer BCP2 does not exhibit structuring at the assembling temperature of the first block copolymer BCP1. The situation is then χₛ₂₋ᵣ₂·Nₜ<10.5 or also χₛ₂₋ᵣ₂·Nₜ<MST curve. In this case, the surface energy of the block “r²” is modulated by the presence of the block “s²” and it is necessary to readjust it so to have an equivalent surface energy with respect to all the blocks of the first block copolymer BCP1. According to this approach, the block “s²” acts in this case only as dissolving group for the block copolymer BCP2. Nevertheless, it should be noted that the surface energy of the blocks of the block copolymer BCP2 depends strongly on the temperature.

Preferably, the time necessary for the organization of the block copolymer BCP2 forming the top coat is less than or equal to that of the first block copolymer BCP1.

Consequently, it is the orientation parallel to the surface of the stack obtained of the patterns generated during the self-assembling of the second block copolymer BCP2 which makes it possible to obtain the perpendicular orientation of the patterns of the first block copolymer BCP1.

Optionally, the block “s²” of the constituent block copolymer BCP2 of the top coat TC can be highly soluble in a solvent or mixture of solvents which is not a solvent or solvent mixture for the first copolymer BCP1 intended to be nanostructured in order to form a nanolithography resist. The block “s²” can then act as an agent which promotes the dissolution of the block copolymer BCP2 in this specific solvent or mixture of solvents, denoted “MS2”, which then makes possible the subsequent withdrawal of the second block copolymer BCP2.

As regards the process for the manufacture of a nanolithography resist, when the film of block copolymer BCP1 is nanostructured and when its patterns are oriented perpendicularly to the surface of the stack, it is appropriate to carry out the withdrawal of the upper layer of top coat TC formed by the second block copolymer BCP2, in order to be able to use the film of nanostructured block copolymer BCP1 as resist in a nanolithography process, in order to transfer its patterns into the underlying substrate. For this, the withdrawal of the block copolymer BCP2 can be carried out either by rinsing with a solvent or mixture of solvents MS2 which is a non-solvent, at least in part, for the first block copolymer BCP1, or by dry etching, such as plasma etching, for example, for which the chemistry(ies) of the gases employed is (are) adapted according to the intrinsic constituents of the block copolymer BCP2.

After withdrawal of the block copolymer BCP2, a film of nanostructured block copolymer BCP1 is obtained, the nanodomains of which are oriented perpendicularly to the surface of the underlying substrate, as represented in the diagram of FIG. 4. This film of block copolymer is then capable of acting as resist, after withdrawal of at least one of its blocks in order to leave a porous film and to thus be able to transfer its patterns into the underlying substrate by a nanolithography process.

Optionally, prior to withdrawal of the constituent block copolymer BCP2 of the upper neutralization layer, a stimulus can additionally be applied over all or part of the stack obtained, consisting of the substrate S, the surface neutralization layer N of the substrate, the film of block copolymer BCP1 and the upper layer of block copolymer BCP2. Such a stimulus can, for example, be produced by exposure to UV-visible radiation, to an electron beam or also to a liquid exhibiting acid/base or oxidation/reduction properties, for example. The stimulus then makes it possible to induce a chemical modification over all or part of the block copolymer BCP2 of the upper layer, by cleaving of polymer chains, formation of ionic entities, and the like. Such a modification then facilitates the dissolution of the block copolymer BCP2 in a solvent or mixture of solvents, denoted “MS3”, in which the first copolymer BCP1, at least in part, is not soluble before or after the exposure to the stimulus. This solvent or mixture of solvents MS3 can be identical to or different from the solvent MS2, according to the extent of the modification in solubility of the block copolymer BCP2 subsequent to the exposure to the stimulus.

It is also envisaged for the first block copolymer BCP1, at least in part, that is to say at least one block constituting it, to be able to be sensitive to the stimulus applied, so that the block in question can be modified subsequent to the stimulus, according to the same principle as the block copolymer BCP2 modified by virtue of the stimulus. Thus, simultaneously with the withdrawal of the constituent block copolymer BCP2 of the upper top coat layer, at least one block of the block copolymer BCP1 can also be removed, so that a film intended to act as resist is obtained. In one example, if the copolymer BCP1 intended to act as resist is a PS-b-PMMA block copolymer, a stimulus by exposure of the stack to UV radiation will make it possible to cleave the polymer chains of the PMMA. In this case, the PMMA patterns of the first block copolymer can be removed, simultaneously with the second block copolymer BCP2, by dissolution in a solvent or mixture of solvents MS2, MS3.

In a simple example where the block copolymer BCP1 intended to act as nanolithography resist has a lamellar morphology and consists of a diblock system of PS-b-PMMA type, then the constituent block copolymer BCP2 of the upper top coat TC layer can be written in the form: s²-b-r²=s²-b-P(MMA-r-S), where the group s² can be a block obtained by polymerization of a monomer of fluoroalkyl acrylate type, for example.

In order to simplify the description, only the atmosphere has been described as constituent compound of the upper interface. However, there exist a large number of compounds or mixtures of compounds capable of constituting such an interface, whether they are liquid, solid or gaseous at the organization temperature of the two block copolymers. Thus, for example, when the compound at the interface consists of a fluoropolymer which is liquid at the annealing temperature of the block copolymers, then one of the constituent blocks of the second block copolymer BCP2, forming the upper neutralization layer, will comprise a fluorinated copolymer.

1-29: (canceled)

30. A process for controlling the surface energy at the upper interface of a first block copolymer (BCP1), comprising:
covering the upper surface of the first block copolymer (BCP1) with an upper surface neutralization layer (TC) comprising a second block copolymer (BCP2),
wherein the first block copolymer (BCP1) has a lower surface in contact with a preneutralized surface of a substrate (S); and
wherein the first block copolymer (BCP1) forms nanodomains that are oriented perpendicularly to the substrate when subjected to a subsequent nanostructuring.

31. The process of claim 30, wherein the first block copolymer (BCP1) and the second block copolymer (BCP2) are blended in a common solvent and are deposited simultaneously, in a single stage, on the preneutralized surface of the substrate.

32. The process of claim 30, wherein the first block copolymer (BCP1) and the second block copolymer (BCP2) are immiscible with one another

33. The process of claim 30, wherein the first block copolymer (BCP1) is deposited on the preneutralized surface of the substrate and then the second block copolymer (BCP2) is deposited on the first block copolymer (BCP1).

34. The process of claim 30, further comprising:
heat treating the first block copolymer (BCP1) and the second block copolymer (BCP2) to nanostructure at least one of the first block copolymer (BCP1) and the second block copolymer (BCP2).

35. The process of claim 34, wherein the heat treatment is conducted in a single stage and at a single temperature.

36. The process of claim 35, wherein the time necessary for the organization of the second block copolymer (BCP2) is less than or equal to that of the first block copolymer (BCP1).

37. The process of claim 34, wherein the heat treatment is conducted in several successive stages at different temperatures and wherein the second block copolymer (BCP2) becomes organized more rapidly, or at lower temperature, than the first block copolymer (BCP1).

38. The process of claim 34, wherein
the second block copolymer (BCP2) is non-structured at the organization temperature of the first block copolymer (BCP1); and
the surface energy of a block, or set of blocks (r^{Z}) of the second block copolymer (BCP2) is modulated by the presence of another block, or set of blocks (s²) so that all of the blocks of the second block copolymer (BCP2) exhibit an equivalent surface energy for each of the blocks of the first block copolymer (BCP1).

39. The process of claim 30, further comprising:
nanostructuring the first block copolymer (BCP1) to form nanodomains that are oriented perpendicularly to the substrate.

40. The process of claim 30, wherein the surface of the substrate (S) is preneutralized by grafting a statistical copolymer to the surface.

41. A process for manufacturing a nanolithography resist, comprising:
(a) covering the upper surface of a first block copolymer (BCP1) with an upper surface neutralization layer (TC) comprising a second block copolymer (BCP2),
wherein the first block copolymer (BCP1) has a lower surface in contact with a preneutralized surface of a substrate (S);
(b) nanostructuring the first block copolymer (BCP1) to form nanodomains that are oriented perpendicularly to the substrate; and then
(c) removing the second block copolymer (BCP2) and at least one of the nanodomains of the first block copolymer (BCP1) to create a film suitable as a nanolithography resist.

42. The process of claim 41, wherein the removing (c) is conducted in one or more successive stages.

43. The process of claim 41, wherein the removing (c) is accomplished by dry etching or by rinsing the second block copolymer (BCP2) in a solvent or mixture of solvents (MS2) in which the first block copolymer (BCP1) is at least partially insoluble.

44. The process of claim 41, further comprising, subsequent to (b) and prior to (c):
(b1) applying a stimulus to at least a portion of at least one of the substrate (S), the preneutralized surface of the substrate (S), the first block copolymer (BCP1) and the second block copolymer (BCP2).

45. The process of claim 44, wherein the stimulus comprises exposing at least a portion of at least one of the substrate (S), the preneutralized surface of the substrate (S), the first block copolymer (BCP1) and the second block copolymer (BCP2) to UV-visible radiation, an electron beam or a liquid exhibiting acid/base or oxidation/reduction properties.

46. The process of claim 44, wherein the removing (c) is accomplished by dissolving the second block copolymer (BCP2) in a solvent or mixture of solvents (MS3) in which the first block copolymer (BCP1) is at least partially insoluble before and/or after the exposure to the stimulus.

47. The process of claim 44, wherein at least one block of the first block copolymer (BCP1) is sensitive to the stimulus, so that it can be removed simultaneously with the second block copolymer (BCP2).

48. An upper surface neutralization layer comprising a second block copolymer (BCP2),
wherein, when the upper surface neutralization layer is in contact with an upper surface of a first block copolymer (BCP1), the first block copolymer (BCP1) forms nanodomains that are oriented perpendicularly to the substrate when subjected to nanostructuring, wherein the first block copolymer (BCP1) has a lower surface in contact with a preneutralized surface of a substrate (S).

49. The upper surface neutralization layer of claim 48, wherein the block copolymer (BCP2) comprises at least two different blocks, or sets of blocks.

50. The upper surface neutralization layer of claim 48, wherein each block of the block copolymer (BCP2) comprises a set of comonomers, copolymerized together into an architecture of block, gradient, statistical, random, alternating or comb type.

51. The upper surface neutralization layer of claim 48, wherein the block copolymer (BCP2) comprises m blocks, wherein m is an integer ≥2 and ≤11.

52. The upper surface neutralization layer of claim 48, wherein the morphology of the block copolymer (BCP2) is lamellar.

53. The upper surface neutralization layer of claim 48, wherein the volume fraction of each block of the block copolymer (BCP2) varies from 5 to 95%, with respect to the volume of the block copolymer.

54. The upper surface neutralization layer of claim 48, wherein the second block copolymer (BCP2) exhibits an annealing temperature which is lower than or equal to that of the first block copolymer (BCP1).

55. The upper surface neutralization layer of claim 48, wherein the block copolymer (BCP2) has a molecular weight between 1,000 and 500,000 g/mol.

56. The upper surface neutralization layer of claim 48, wherein each block (i² . . . j²) of the block copolymer (BCP2) comprises comonomers present in the backbone of the first block copolymer (BCP1).

57. The upper surface neutralization layer of claim 48, which is in contact with a compound or mixture of compounds of defined constitution and of defined surface energy, which can be solid, gaseous or liquid at the temperature of organization of the first block copolymer (BCP1) and the second block copolymer (BCP2).

58. The upper surface neutralization layer of claim 48, wherein the block copolymer (BCP2) comprises a first block, or set of blocks (s²), the surface energy of which is the lowest of all of the constituent blocks of the first block copolymer (BCP1) and the second block copolymer BCP2, and a second block, or set of blocks (r²) exhibiting a zero or equivalent affinity for each of the blocks of the first block copolymer (BCP1).

59. The upper surface neutralization layer of claim 58, wherein the first block, or set of blocks (s²) the energy of which is lowest, exhibits a volume fraction of between 50% and 70%, with respect to the volume of the second block copolymer (BCP2).

60. The upper surface neutralization layer of claim 58, wherein the first block, or set of blocks (s²) the energy of which is lowest, is soluble in a solvent or solvent mixture (MS2), so that the second block copolymer (BCP2) dissolves in the solvent or solvent mixture (MS2) when the second block copolymer (BCP2) is treated with the solvent or solvent mixture (MS2).

61. The upper surface neutralization layer of claim 48, wherein the second block copolymer (BCP2) is in contract with an upper surface of a first block copolymer (BCP1).

62. The upper surface neutralization layer of claim 61, wherein the first block copolymer (BCP1) has a lower surface in contact with a preneutralized surface of a substrate (S).
